(19) United States
(12) Patent Application Publication
(10) Pub. No.: US 2024/0038803 A1
(43) Pub. Date: Feb. 1, 2024

(54) PROCESS FOR AREA-SELECTIVE ATOMIC LAYER DEPOSITION OF ANTIREFLECTION COATINGS AND FILTERS

(71) Applicant: California Institute of Technology, Pasadena, CA (US)

(72) Inventors: April D. Jewell, Pasadena, CA (US); Shouleh Nikzad, Pasadena, CA (US); John J. Hennessy, Pasadena, CA (US); Ghazaleh Kafaie Shirmanesh, Pasadena, CA (US); Erika T. Hamden, Pasadena, CA (US)

(73) Assignee: California Institute of Technology, Pasadena, CA (US)

(21) Appl. No.: 18/360,969

(22) Filed: Jul. 28, 2023

Related U.S. Application Data
(60) Provisional application No. 63/393,003, filed on Jul. 28, 2022.

(51) Int. Cl. H01L 27/146; G02B 5/28; G02B 1/115

(52) U.S. Cl. CPC H01L 27/14623; G02B 5/288; G02B 1/115; H01L 27/14685

(57) ABSTRACT

A process for fabricating a light detector with one or more antireflection (AR) and/or bandpass filter coatings deposited thereon by area-selective atomic layer deposition (ALD). The AR coatings may comprise a metal oxide or a metal fluoride, such as AlF₃, Al₂O₃, and/or HfO₂, and the bandpass filter coatings may comprise solar-blind bandpass filter coatings. The AR and/or bandpass filter coatings may be deposited with different thicknesses on different portions of the light detector using an intentional and controllable patterning by a lithography-based process. As a result, the AR and/or bandpass filter coatings provide a butcher-block style response profile with each of the different portions of the light detector targeting a specific bandpass of light. The AR and/or bandpass filter coatings comprise a linear variable filter (LVF) that provides a spatially varying response by the light detector.

### CROSS REFERENCE TO RELATED APPLICATION(S)

This application claims the benefit under 35 U.S.C. Section 119(e) of the following co-pending and commonly-assigned application(s):

U.S. Provisional Application Ser. No. 63/393,003, filed on Jul. 28, 2022, by Shouleh Nikzad, April D. Jewell, John J. Hennessy, Ghazaleh Kafaei Shirmanesh and Erika T. Hamden, entitled “PROCESS FOR AREA-SELECTIVE ATOMIC LAYER DEPOSITION OF ANTIREFLECTION COATINGS AND FILTERS,” docket number CIT 8858-P;

which application(s) is/are incorporated by reference herein.

### STATEMENT REGARDING FEDERALLY SPONSORED RESEARCH AND DEVELOPMENT

This invention was made with government support under Grant No. 80NMO0018D0004 awarded by NASA (JPL). The government has certain rights in the invention.

### BACKGROUND OF THE INVENTION

### 1. Field of the Invention

This invention relates to a process for area-selective atomic layer deposition (ALD) of antireflection (AR) and/or bandpass filter coatings, and a resulting device and manufacture.

### 2. Description of the Related Art

(This application references a number of different publications as indicated throughout the specification by one or more reference numbers in brackets, e.g., [x]. A list of these different publications ordered according to these reference numbers can be found below in the section entitled “References,” wherein each of these publications is incorporated by reference.)

Two-dimensional (2D) doping processes developed by the Jet Propulsion Laboratory (JPL) at the California Institute of Technology (Caltech) have been proven to exhibit nearly 100% internal quantum efficiency (QE) (i.e. reflection-limited response) from extreme ultraviolet (UV) to the near infrared (NIR). The response can be further optimized and tailored with AR coatings and/or bandpass filters. However, due to silicon's optical properties, there is no “one size fits all” solution that can span the entire UV to NIR wavelength range.

Moreover, spectroscopy applications often benefit from a spatially varying detector response optimized according to the instrument's optical dispersion. Spatially varying the detector response to correspond with instrument dispersion requires that different coatings be applied to different portions of the detector.

### SUMMARY OF THE INVENTION

The present invention demonstrates detectors with a butcher-block style response profile with each portion of the device targeting a specific bandpass, in a manner similar to a linear variable filter (LVF). In one or more embodiments, this technological advancement is achieved through an intentional and controllable patterning of AR and/or bandpass filter coatings on a silicon-based light detector, e.g., a photodetector. The present invention also discloses various implementations and deployments of photodetectors, such as two-dimensional (2D) doped UV detectors, with AR and/or bandpass filter coatings, as well as variable response UV detectors.

Example embodiments include, but are not limited to, the following.

1. A method, comprising:
providing a detector (e.g., silicon light detector or silicon imager) of electromagnetic radiation; and
selectively depositing one or more antireflection (AR) and/or bandpass filter coatings on the detector, wherein the AR and/or bandpass filter coatings are selectively deposited on different portions of the light detector to provide a butcher-block style response profile with each of the different portions of the light detector targeting a specific bandpass of the electromagnetic radiation.

2. The method of example 1, wherein the AR and/or bandpass filter coatings are deposited with different materials and/or different thicknesses on the different portions of the detector.

3. The method of example 2, wherein the AR and/or bandpass filter coatings are deposited by atomic layer deposition (ALD).

4. The method of example 3, wherein the ALD is an area-selective ALD.

5. The method of example 4, wherein the area-selective ALD comprises an intentional and controllable patterning by a lithography-based process.

6. The method of example 5, wherein a lithography mask is placed directly on a surface of the detector preventing deposition by ALD in unwanted areas.

7. The method of example 1, wherein the AR coatings comprise a metal oxide or metal fluoride.

8. The method of example 1, wherein the bandpass filter coatings comprise solar-blind bandpass filter coatings.

9. The method of example 1, wherein the AR and/or bandpass filter coatings together comprise one or more linear variable filters (LVFs) that provide a spatially varying response by the detector.

10. The method of example 1, wherein the light detector consists essentially of silicon.

11. The method of example 1, wherein the light detector comprises a two-dimensional (2D) doped ultraviolet (UV) light detector, a delta-doped UV light detector, or a superlattice-doped UV light detector.

12. A device manufactured by the method of example 1.

13. A device, comprising:
a detector of electromagnetic radiation; and
one or more antireflection (AR) and/or bandpass filter coatings deposited on a surface of the light detector, wherein the AR and/or bandpass filter coatings are deposited on different portions of the light detector to provide a butcher-block style response profile with each of the different portions of the detector targeting a specific bandpass of the electromagnetic radiation.

14. The device of example 13, wherein the AR and/or bandpass filter coatings are deposited with different materials and/or different thicknesses on the different portions of the detector.

15. The device of example 13, wherein the AR and/or bandpass filters are deposited with sub-nanometer precision.

16. The device of example 13, wherein the light detector consists essentially of a single material across the patterned surface

17. The device of example 16, wherein the light detector consists essentially of silicon.

18. The device of example 17, wherein the light detector comprises a delta doped or a superlattice doped surface layer providing passivation of a near-surface band structure.

19. The device of example 17, wherein the AR and/or bandpass filter coatings each have a bandwidth tailored for the different frequency response of the silicon to ultraviolet (UV) light, so that the detector has a quantum efficiency greater than 50% for UV wavelengths between 110 nm and 300 nm.

20. The device of example 13, wherein the AR coatings comprise a metal oxide or a metal fluoride and/or the filter is a Fabry Perot cavity comprising a reflective metal layer between two dielectric layers.

### BRIEF DESCRIPTION OF THE DRAWINGS

Referring now to the drawings in which like reference numbers represent corresponding parts throughout:

FIG. 1 is a graph of the Index of Refraction (n) vs. Wavelength (nm) and Extinction Coefficient (k) vs. Wavelength (nm) illustrating that the optical properties of silicon (Si) vary widely throughout UV wavelengths.

FIG. 2 is a graph of Quantum Efficiency (QE) (%) vs. Wavelength (nm) that illustrates the response of several AR-coated, delta-doped detectors. Each spectral region was targeted using a single-layer AR coating; in this example, HfO₂ and Al₂O₃ were deposited by ALD. Plot adapted from ([18] Nikzad et al. 2012).

FIGS. 3A and 3B are images of an 8-inch diameter backside-illuminated complementary metal-oxide semiconductor (CMOS) wafer before (FIG. 3A) and after (FIG. 3B) application of a multi-layer AR coating that shows the high uniformity afforded by the ALD process.

FIG. 4A is a graph of Model Transmittance (T) (%) vs. Wavelength (nm) where performance models for a bare 2D-doped detector is compared to Faint Intergalactic Red-shifted Emission Balloon (FIREBall-2) targeted AR coatings with one, three, and five layers.

FIG. 4B is a graph of QE (%) vs. Wavelength (nm) that illustrates the measured QE for a 2D-doped device with the FIREBall 5-layer coating. The plots show quantum yield (QY) corrected data using literature ([13] Kuschnerus et al. 1998) and calculated correction factors, respectively. Adapted from ([4] Hamden et al. 2016b; [11] Jewell et al. 2015).

FIG. 5 is a graph of Model T (%) vs. Wavelength (nm) with plots showing model T performance for several 3 layer (3L) metal-dielectric filters (MDFs) with the thickness of the dielectric layers varied. The plots are labeled according to the center wavelength (CWL).

FIG. 6 is a graph of Model T (%) vs. Wavelength (nm) with plots showing model T performance for several MDFs with varying number of layers and varying metal layer thicknesses.

FIGS. 7A, 7B, 7C, 7D, 7E and 7F are examples of broadband and multiband AR coating/filter designs that can be patterned onto silicon detectors. Schematics of LVFs for broadband response based on using the same material at different thickness (left in FIGS. 7A and 7B, and center in FIGS. 7C and 7D) and different materials (right in FIGS. 7E and 7F).

FIG. 8A is a photograph of a delta-doped die following deposition of two AR coated regions comprising two different thicknesses of alumina (Al₂O₃).

FIG. 8B is a graph of Model QE (%) vs. Wavelength (nm) with plots showing the expected sensitivity of the two coated regions as well as the uncoated Si.

FIGS. 9A and 9B are first-light test images from a delta-doped device with a block filter coating, wherein FIG. 9B is an enlarged image of a portion of FIG. 9A. The boxes in FIG. 9A correspond to the regions/curves shown in FIGS. 8A and 8B.

FIG. 10A is a graph of Model QE (%) vs. Wavelength (nm) with plots showing the potential performance of a patterned AR coating based on AlF₃, Al₂O₃, and HfO₂; the plots trace the maximum sensitivity at each wavelength.

FIG. 10B is a photograph of a substrate prepared with the LVF described by the plots in FIG. 10A.

FIG. 11 is a flowchart that illustrates the steps for a process for area-selective ALD of AR and/or bandpass filter coatings, and a resulting manufactured device.

FIG. 12 is a schematic illustrating ALD deposition of a patterned AR and/or bandpass filter coating on a detector.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

1. Introduction

For missions of all sizes, a goal is to squeeze every ounce of capability out of the system components, and the detector is no exception. Silicon detectors continue to be developed with excellent attributes especially in low noise, small pixel size, and high pixel count. Scientific charge-coupled devices (CCDs) have been the workhorse detectors for large mosaic focal plane arrays (FPAs), such as used in the Kepler Space Telescope, Euclid Space Telescope, and Gaia Space Telescope. Low-noise CMOS FPAs (e.g., from Teledyne-e2v™, SRI International™) have significant advantages in low-power, versatile readout, and radiation tolerance (no charge transfer inefficiency in space environment) and are particularly promising for populating future gigapixel FPAs.

In addition to enabling large Probe-class and Flagship mission concepts, silicon detectors are well-suited for small satellite (SmallSat) missions. CCD and CMOS cameras can be made quite small, and the detectors themselves have relatively modest power and cooling requirements. In recent years, silicon detector technology has advanced to the point that SmallSat missions are now capable of performing measurements previously possible only in a larger platform. CubeSats are a subset of SmallSats with a total volume of anywhere from 1 to 27 units (U) (1 U=10 cm×10 cm×10 cm) and a total mass of no more than ˜1.3 kg/U ([21] Puig-Suari et al. 2002). We have entered an era when these small, relatively inexpensive platforms can be used to answer compelling scientific questions ([23] Shkolnik 2018).

The choice of detector architecture for future missions will largely depend on the science requirements and instrument design. However, the recent Astro NASA's Astrophysics Technology Development Offices recently released the 2022 Astrophysics Strategic Technology Gap List (Astrophysics Program Offices: Technology Development 2022) aimed at defining the overarching technology needs of the astrophysics community. The gap list calls out several technologies and performance goals related to UV imaging and spectroscopy, as shown in Table 1 below, many of which can be addressed by the ongoing detector and coatings technology development work at JPL.

TABLE 1
Astrophysics Technology Gaps related to UV detector
and coatings performance goals and objectives.

| Gap Name | Performance Goals and Objectives |
|---|---|
| Photon Counting Large-format UV | QE >~60% for 100-300 nm wavelengths. |
| Detectors | |
| Large-Format, Low-Darkrate, High- | Quantum Efficiency: >30% between 100- |
| Efficiency, Photon-Counting, Solar-blind, | 200 nm. Solar blindness appropriate to the |
| Far-UV (FUV) and Near-UV (NUV) | Mission. |
| Detectors | |
| High-Throughput Bandpass Selection for | Key Objectives Single Filters: |
| UV/VIS (visible) - Single Filter and Detector | Red-blocking transmittance: >50-75% |
| Integrated | (UV), <0.0001%-0.01% Vis-NIR; and |
| | T (Vis) >0.9. |
| | Key Objectives Detector-Integrated Filters: |
| | red rejection, narrowband or |
| | broadband anti-reflection coatings on Si delta- |
| | doped detectors, or bandpass tuning and red |
| | rejection photocathodes in large device |
| | formats. |
| High-QE, Solar-blind, Broad-band NUV | QE > 50% over the full NUV wavelength |
| Detector | range (180-400 nm) but extremely insensitive |
| | (QE < 10⁻³) to out-of-band light (i.e. solar- |
| | blind). |
| FUV Imaging Bandpass Filters | Medium (20 nm) and wide (40 nm) filter |
| | set covering 100-200 nm |
| | Work with shaped optics: |
| | >80% peak reflectance within central |
| | 15 nm for medium band filters, |
| | >60% peak reflectance within central |
| | 30 nm for wide band filters, and |
| | <1% transmission at 121.6 nm and <1E−4 |
| | transmission at >300 nm when |
| | combined with solar blind detector systems. |

### 2. Example High Performance UV Detector Optimization

Regardless of detector architecture and readout scheme, silicon imagers must be back illuminated and properly passivated to achieve NASA's science objectives. At JPL, the approach to device passivation uses delta-doping and superlattice-doping, both referred to as 2D-doping. JPL's 2D-doping process places the dopant within a few nanometers of the back surface, effectively eliminating the dead layer and extending device responsivity well into the UV. The result is 100% internal QE (i.e., reflection limited response) from soft X-ray to the

near infrared ([9] Hoenk et al. 1992, 2009; [19] Nikzad et al. 2017). As with most silicon-based detectors, the external QE (device response) can be further improved and optimized with AR coatings to mitigate reflection losses or bandpass filters to reject unwanted light.

2.1. Example Antireflection Coatings

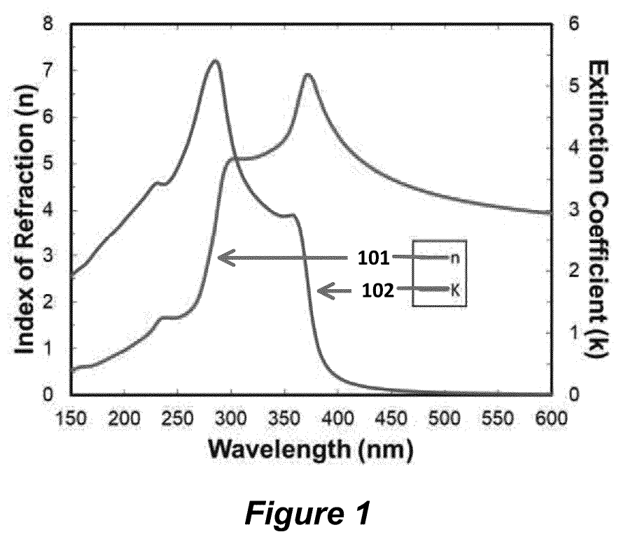

There are several considerations to be made when selecting AR coatings for UV detectors. The choice of material is limited to UV-transmissive materials—typically metal oxides and metal fluorides. Quarter wave optical thicknesses (and thus physical thicknesses) are on the order of a few tens of nanometers, so the deposition technique used must allow for nanometer-scale control of film thickness. The most critical consideration, however, is the silicon substrate itself, which has widely varying optical properties throughout the UV wavelength range, as shown in FIG. 1, which illustrates that the optical properties of silicon, including both the index of refraction (n) represented by the plot 101 and the extinction coefficient (k) represented by the plot 102, vary widely throughout the UV. Because of silicon's optical behavior, there is no “one size fits all” AR coating or bandpass filter that will result in high transmission throughout the entire UV range. However, the inventors' team has previously demonstrated that with appropriate material selection and well-controlled deposition processes significant improvements in UV detector QE can be realized.

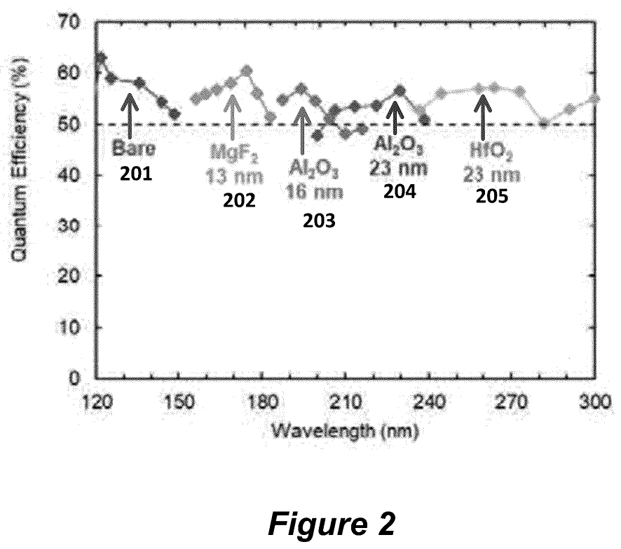

FIG. 2 shows the response of several AR-coated, delta-doped detectors, including, from left to right, the bare delta-doped detector 201, as well as delta-doped detectors coated with 13 nm of MgF₂ 202, 16 nm of Al₂O₃ 203, 23 nm of Al₂O₃ 204, and 23 nm of HfO₂ 205, wherein each spectral region was targeted using either the bare delta-doped detector 201 or a delta-doped detector with a simple single-layer AR coating. In this example, Al₂O₃ 203, 204 and HfO₂ 205 were deposited by ALD, while MgF₂ 202 was deposited by thermal evaporation; an ALD-MgF₂ process has since been developed ([8] Hennessy et al. 2015a). The plot was adapted from ([18] Nikzad et al. 2012).

This demonstration achieved QE>50% throughout the 130-300 nm range; this a marked improvement over the reflection limit of 30-40% for this wavelength range. Note that each detector was optimized using a different AR coating and the average bandwidth (defined here as the wavelength range where QE>50%) is limited to only a few tens of nanometers ([18] Nikzad et al. 2012).

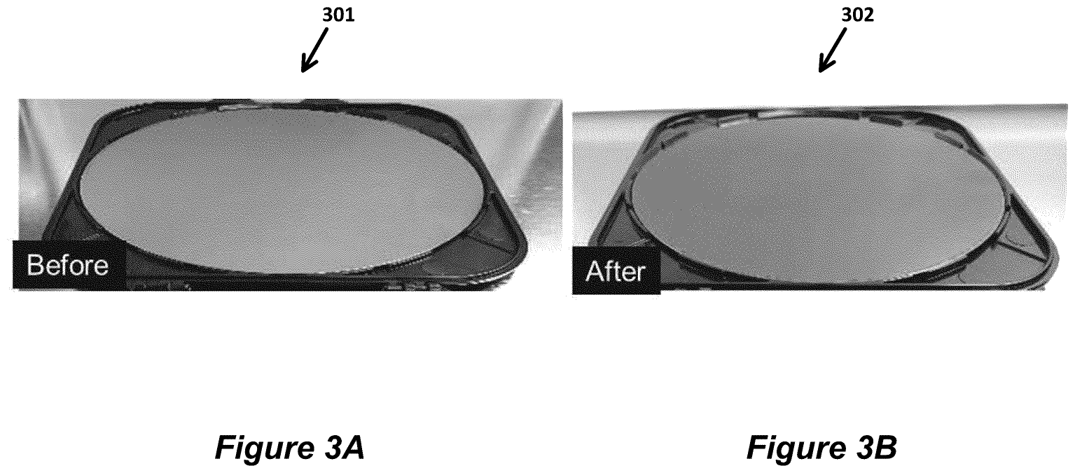

JPL's AR coatings are prepared by ALD, a process in which films are deposited a single monolayer at a time through a series of self-limiting half reactions at the substrate surface. ALD allows for sub-nanometer-scale control of film thickness and results in uniform, as shown in FIGS. 3A and 3B, which are images of an 8-inch diameter backside-illuminated CMOS wafer before (301 in FIG. 3A) and after (302 in FIG. 3B) application of multi-layer AR coating show the high uniformity afforded by the ALD process, resulting in pin-hole-free films as well as sharp, well-defined interfaces in multi-layer films ([12] Jewell et al. 2013).

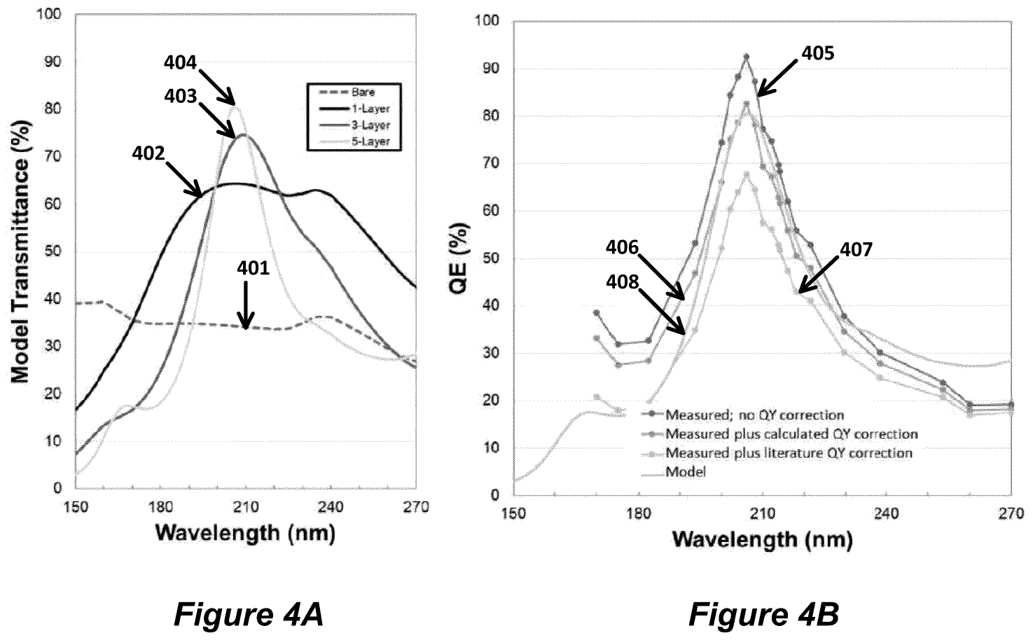

Further improvement in detector QE can be achieved with multi-layer AR coatings, which the inventors' team has taken advantage of on the FIREBall-2 mission. FIREBall-2 is a suborbital balloon mission designed to discover and map faint emission from the circumgalactic medium of low redshift galaxies (0.3<z<1.0). Measurements are performed from an altitude of ˜120,000 feet with a detector optimized for the stratospheric UV window centered at ˜215 nm. As shown above, with a single layer AR coating the detector could be expected to achieve ˜60% QE in the FIREBall band; however, use of a multi-layer AR coating allows for further optimization of detector response and>80% QE, as shown in FIGS. 4A and 4B ([4,3] Hamden et al. 2016a, 2020; [11] Jewell et al. 2015).

Specifically, FIG. 4A shows performance models for a bare 2D-doped detector (dashed plot 401) is compared to FIREBall-targeted AR coatings with one layer (plot 402), three layers (plot 403), and five layers (plot 404).

FIG. 4B shows the measured QE (plot 405) for a 2D-doped device with the FIREBall 5-layer coating. The plots 406 and 407 show quantum yield (QY) corrected data using literature ([13] Kuschnerus et al. 1998) and calculated correction factors, respectively. Adapted from ([5] Hamden et al. 2016b; [11] Jewell et al. 2015). The plot 408 represents the model.

2.2. Example Solar-Blind Bandpass Filters

JPL's 2D doping and AR coatings address some of the materials challenges limiting UV imaging and spectroscopy performance; however, an additional challenge arises due to the fact that most UV signals of interests are comingled with a strong visible background (e.g., stellar or coronal radiation). 2D-doped silicon devices have high UV QE extending to the Si bandgap energy at ˜1.1 eV (˜1100 nm); thus, isolating the UV signal requires blocking of the out-of-band light. The inventors have previously demonstrated bandpass filters integrated directly onto Si sensors, which allow one to maintain the high in-band QE while rejecting long-wavelengths ([8,7] Hennessy et al. 2015b, 2018). These metal-dielectric filters (MDFs) are structures composed of an aluminum reflector layer sandwiched between two dielectric layers; the Si substrate itself also acts as a reflector layer for the integrated filter stack. The choice of dielectric can be tailored to optimize in-band performance to the intended application. Using ALD to deposit the dielectric layer results in access to a variety of materials and sub-nanometer scale control over the layer thickness, which lends great versatility to the design of these visible-blind filters.

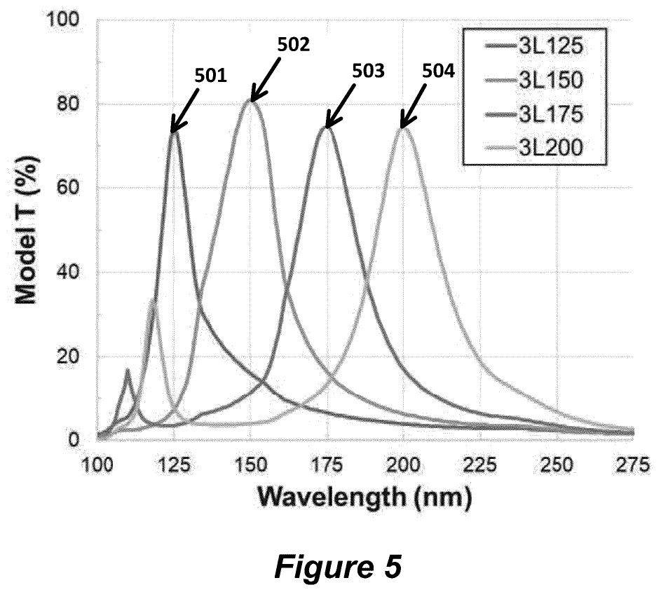

For example, FIG. 5 shows model transmission (T) for multiple three-layer (3L) MDFs, each including two dielectric layers and one metal layer (i.e., AlF₃/Al/AlF₃), where only the thickness of the dielectric layers is varied. The plots are labeled according to the CWL, which transitions from 125 nm to 200 nm, wherein plot 501 represents 3L 125 nm, plot 502 represents 3L 150 nm, plot 503 represents 3L 175 nm, and plot 504 represents 3L 200 nm.

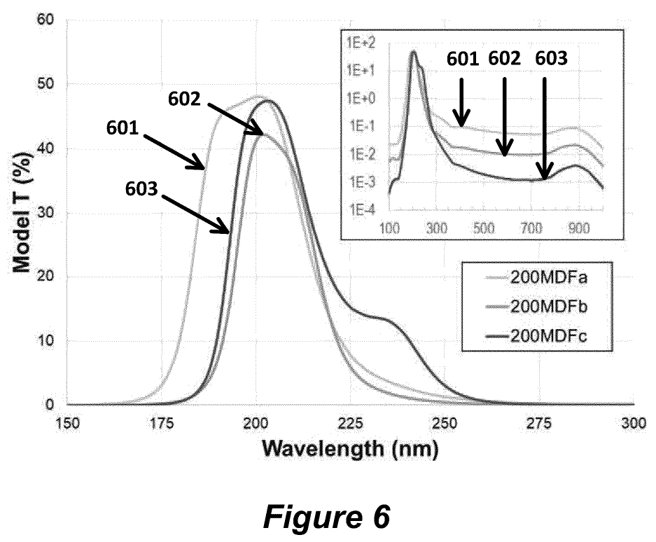

Similarly, FIG. 6 has plots showing model T performance for several MDFs with the same CWL of 200 nm, varying number of layers and varying metal layer thicknesses, but varying out-of-band blocking efficiencies. Filters 200MDFa represented by plot 601 and 200MDFb represented by plot 602 are both five-layer (SL) designs, including three dielectric layers and two Al layers (i.e., Al₂O₃/Al/Al₂O₃/Al/Al₂O₃), with a total/cumulative Al (Al₂O₃) thicknesses of 35 (82) nm and 45 (88) nm, respectively. The plots 601, 602 show that even fairly small changes in the absolute thicknesses of the filter layers results in significant differences in the in-band peak height and width as well as the in-band/out-of-band throughput ratio (RIO). Filter 200MDFc represented by plot 603 is a seven-layer (7L) design (Al₂O₃/Al/Al₂O₃/Al/Al₂O₃/Al/Al₂O₃) with total/cumulative Al (Al₂O₃) thickness of 50 (125) nm. The additional layers in the 7L design allow for the recovery of some of the in-band throughput lost in 200MDFb 602 while simultaneously offering a higher R_{IO}.

2.3. Example Linear Variable Filters

UV-Visible (Vis) spectroscopy has been recognized as an important channel for astrophysical discovery since the High-Resolution Spectrograph (HRS) and Faint Object Spectrograph (FOS) on the Hubble Space Telescope (HST). Since the launch of HST, several UV telescopes, including the Galaxy Evolution Explorer (GALEX) and the Far Ultraviolet Spectroscopic Explorer (FUSE), have made groundbreaking discoveries in regimes as diverse as galaxy evolution, star formation, and molecular cloud chemistry. HST's Cosmic Origins Spectrograph (COS) has made great strides in observing the environments of nearby galaxies. UV-Visible spectroscopy is also directly applicable to planetary science missions. UV observations of solar system objects have been ongoing for 50+years, and UV instrumentation has been ubiquitous in planetary missions, including Mariner 5 (1967), Voyager 1 & 2 (1977), JUNO (2011), and Europa Clipper (2024) to name only a few.

Thus far, this disclosure has presented AR coatings and bandpass filter solutions based on uniform detector sensitivity. However, spectroscopy applications often benefit from spatially varying wavelength response optimized according to the instrument's optical dispersion. In order to achieve multiple channel or broadband detector response, the coatings and filters must be patterned on the detector. Typically, spatial patterning of system/detector response has been achieved with stand-alone filters. However, placement of a filter mosaic above the sensors causes loss of imaging areas where the converging beam spans more than one filter. Large focal planes may be made with a mosaic of sensors but the mounting of individual filters increases gaps. Single sensors with multiple filters must abandon the pixels which receive light from multiple filters causing significant loss of useful area for small sensors. Placing the filter surface closer to the sensor reduces the gaps but concentrates the filter ghost which is most intense at the edges the bandpass where the interference filter makes the transition from being transmissive to reflective. Placing the filter coating on the detector surface not only reduces the gaps in the image but entirely eliminates the filter ghost. Thus, AR coatings and device-integrated filters enable reduction in optical design complexity and instrument costs, while also improving throughput.

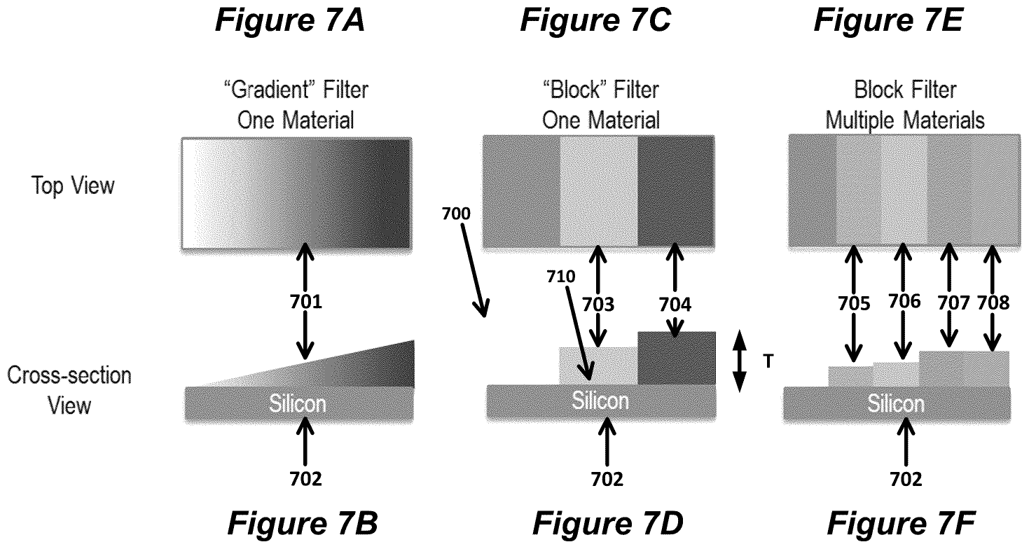

Several examples of linear variable filters (LVFs) based on broadband and multiple channel coating and filter schemes are shown in FIGS. 7A-7F, which are examples of broadband and multiband AR coating/filter designs that can be patterned onto silicon detectors. These include gradient LVFs based on a single material and block-type LVFs based on one or more materials. This disclosure focuses on block type filters.

Specifically, FIGS. 7A and 7B are a top view and cross-section view of a “gradient” filter comprised of one material 701 deposited on an Si substrate 702; FIGS. 7C and 7D are a top view and cross-section view of a “block” filter comprised of two materials 703, 704 deposited on an Si substrate 702; and FIGS. 7E and 7F are a top view and cross-section view of a “block” filter comprised of more multiple materials 705, 706, 707, 708 deposited on an Si substrate 702. These schematics of LVFs for broadband response are based on using the same material at different thickness (for FIGS. 7A-7B and 7C-7D) and different materials (FIGS. 7E-7F).

There have been previous reports on early attempts to pattern ALD-based AR coatings on delta-doped detectors. For this disclosure, the approach was to use a physical shadow mask to screen or block the portion of the substrate that was to remain bare. However, ALD is not a line of sight deposition technique and reactant molecules were able to infiltrate the masked region, resulting in non-uniform film deposition in that area ([2] Greer et al. 2013). Because of this, chemical means of blocking ALD films were explored.

The patterning of ALD-based films is not a new concept, but its application to optical sensors is. Work in “area-selective” ALD (AS-ALD) has typically relied on depositing self-assembled monolayers (SAMs) or small molecule inhibitors (SMIs) to chemically “deactivate” the area of the substrate that is to remain uncoated ([14] Lee et al. 2021; [16] Liu & Bent 2021; [25] Yarbrough et al. 2021). These approaches often depend on having chemically varying substrate materials at the deposition surface and are usually only reliable for blocking deposition of the first 50-100 cycles, equivalent to 5-10 nm. For this application, the substrate material is uniform silicon and the deposited film thickness is on the order of 10s of nm; thus, the application cannot rely on SAMs or SMIs to act as the ALD blocking layers and alternative approach needed to be developed.

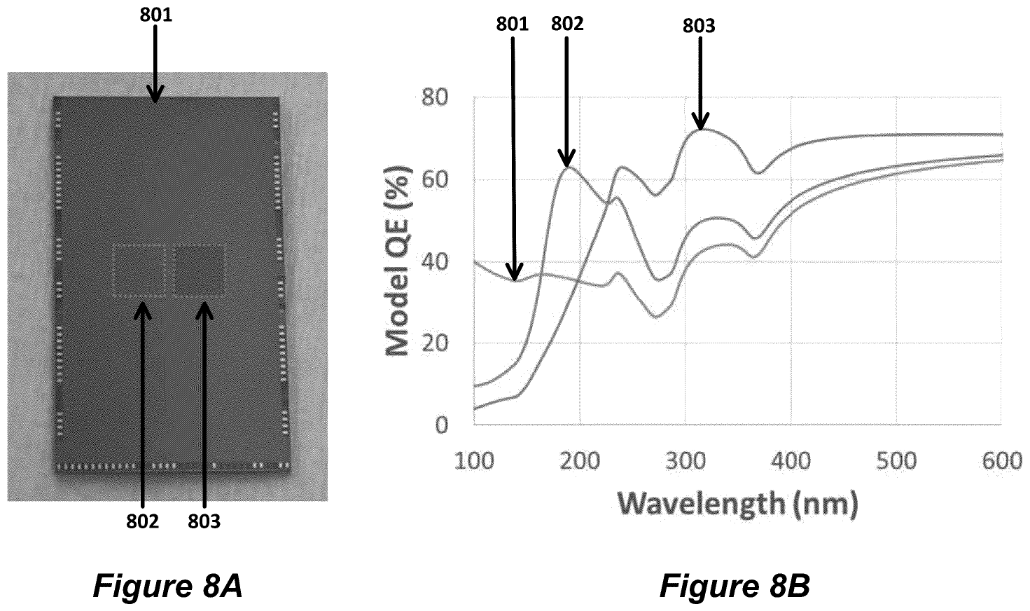

To that end, a lithography-based process has been developed to pattern AR coatings deposited by ALD; this process relies on well-established lithographic patterning techniques already in use in the Microdevices Laboratory at JPL. The advantages of this approach are that it is already known to be compatible with silicon device processing and all the tools required are part of a typical fabrication cleanroom equipment suite. Following successful process development on silicon substrates, a live device was prepared with two AR-coated regions comprising two different thicknesses of Al₂O₃, as shown in FIGS. 8A and 8B.

Specifically, FIG. 8A is a photograph of delta-doped die 801 following deposition of two AR coated regions 802, 803 comprising two different thicknesses of alumina (Al₂O₃). FIG. 8B are plots showing the expected sensitivity of the two coated regions 802, 803, as well as the uncoated Si 801.

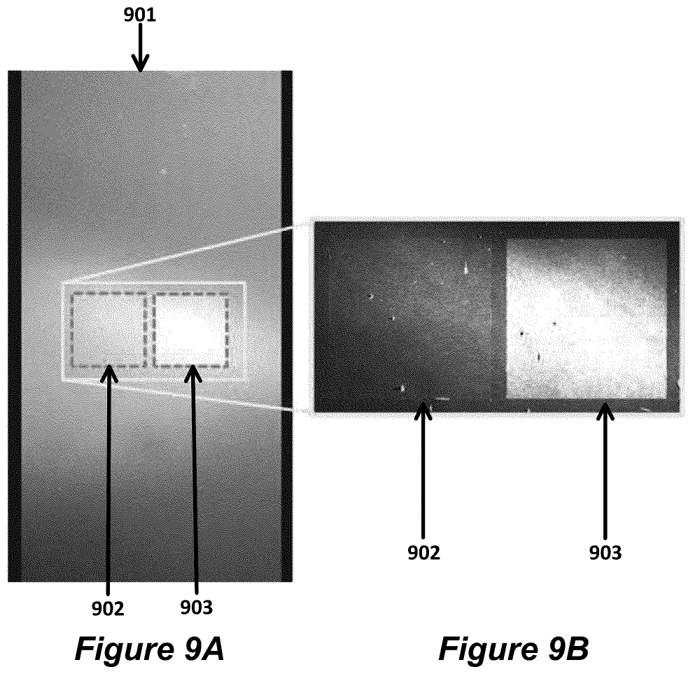

FIGS. 9A and 9B are a first-light test image from a delta-doped device 901 with block filter coatings 902, 903, wherein FIG. 9B is an enlargement of the indicated portion of FIG. 9A containing the two AR coated regions 902, 903. The AR coated regions 902, 903 correspond to the two AR coated regions 802, 803 shown in FIG. 8A and the plots 802, 803 in FIG. 8B.

The first-light test image acquired at room temperature and under visible light illumination demonstrates: (1) device functionality and (2) the AR coatings are performing as intended. The brighter area 903 on right hand side of the image corresponds to R2 and shows higher QE than the bare Si 901 in the visible, while the area 902 on the left hand side of the image corresponds to R1 is expected to be nearly indistinguishable from the bare Si 901 at visible wavelengths. In depth characterization of the device performance (QE, noise, etc.) are ongoing.

3. Example Applications and Potential Implementations

Instrumentation and missions currently under development are well-poised to take advantage of butcher block style LVF technology presented in the previous section.

JPL's Advanced UV Imaging Spectrometer (AUVIS) is a compact instrument designed with advanced technologies (detectors, coatings) to achieve the same or better performance as similar/heritage instrumentation but with reduced size, mass, and power requirements (Carver 2021). The current AUVIS design is a two-channel spectrometer; the far UV (FUV channel spans 120-250 nm, and the near UV (NUV)-visible channel spans 250 to 600 nm. The instrument uses two delta-doped UV detectors optimized with single-layer AR coatings, and, while highly efficient, the throughput of AUVIS is primarily limited by the detectors' varying responses within the two bands.

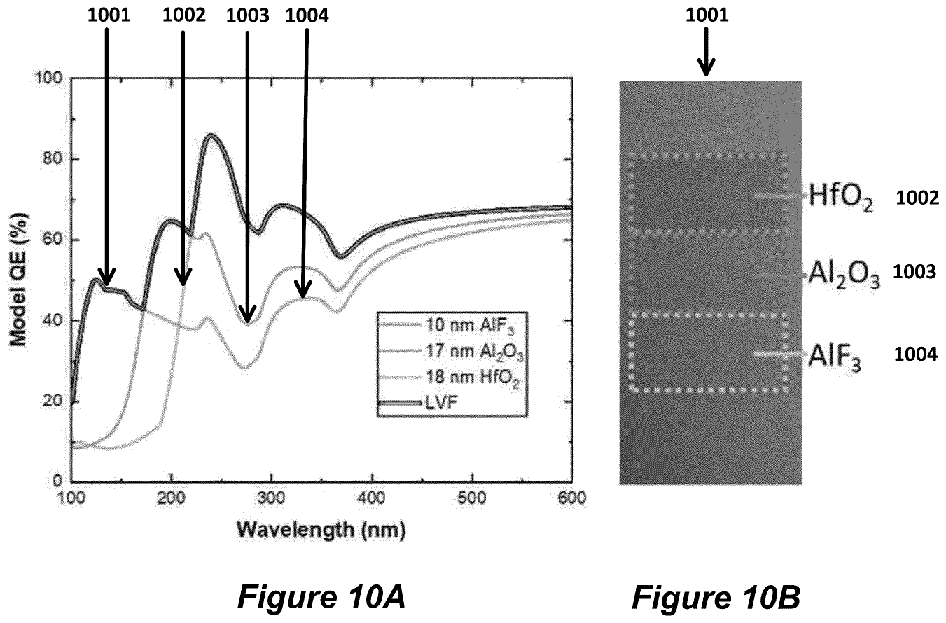

Optimization of the AUVIS detector through the integration of a LVF similar to the one shown in FIG. 10 would allow for higher sensitivity/throughput across the UV spectral range without impacting the instrument's size, mass, power, or operation. This LVF is based on a simple patterned design with single layer AlF₃, Al₂O₃, and HfO₂ AR coatings and has already been demonstrated on silicon substrates. Detector demonstrations are in process, along with fabrication completion.

FIG. 10A shows plots of the potential performance of patterned AR coatings, and FIG. 10B is a photograph of a substrate prepared as an LVF 1001 based on patterned AR coatings of HfO₂ 1002, Al₂O₃ 1003, and AlF₃ 1004. The plots of FIG. 10A trace the maximum sensitivity of the LVF 1001 and patterned AR coatings of HfO₂ 1002, Al₂O₃ 1003, and AlF₃ 1004 at each wavelength.

Mission concepts currently under development that could benefit from an LVF design similar to that shown in FIG. 10B (i.e. using the same materials) include:
UV-SCOPE: The Ultraviolet Spectroscopic Characterization of Planets and their Environments is a Medium Explorer (MidEx) mission concept to “determine the causes of atmospheric mass loss in exoplanets, investigate the mechanisms driving aerosol formation in hot Jupiters, and study the influence of the stellar environment on atmospheric evolution and habitability” ([26] Ardila et al. 2022 SPIE Astronomical Telescopes+Instrumentation. 12181-1). See also ([15] Line et al. 2021; [17] Loyd et al. 2021; [24] Shkolnik et al. 2021). The UV-SCOPE spectral range spans 120 to 400 nm, which will be dispersed across two delta-doped UV detectors.
Polstar: A MidEx mission concept designed to determine “how circumstellar gas flows alter massive stars' evolution, and finding the consequences for the stellar remnant population and the stirring and enrichment of the interstellar medium” ([22] Scowen et al. 2021). (See also [27] 2022 SPIE Astronomical Telescopes+Instrumentation. 12181-4; 12181-11; 12181-121.) The Polstar spectral range spans 122-320 nm.
BHAGERA: The Black Hole Accretion and Growth Experiment with Reverberation Analysis small satellite (SmallSat) mission concept is intended to determine the size of the accretion disks around supermassive black holes at the centers of active galactic nuclei (https://tinyurl.com/fjean7k7). BHAGERA spectra will span 140-600 nm.

4. Example Models

The device performance models presented herein were developed using the TFCalc™ software package.([25] TFCalc: Thin Film Design Software for Windows 2009). Index of refraction data for silicon, aluminum, and various metal oxides and metal fluorides were taken from Palik and the Sopra database. ([20] Palik 1998; [25] TFCalc: Thin Film Design Software for Windows 2009.) Optical properties often vary depending on the deposition method; thus optical constants data collected using laboratory prepared samples ([28] Horiba UVISEL 2; [29] J. A. Woollam VUV-VASE) were also used where appropriate.

5. Alternatives and Modifications

A number of alternatives and modifications are available for the present invention, as set forth below:
The UV detector may use different substrates and different materials.
The UV detector may have a different structure.
Other materials may be used for the AR and/or bandpass filter coatings.
Other deposition techniques may be used for the AR and/or bandpass filter coatings.
Other applications may benefit from the present invention.

6. Example Process Steps

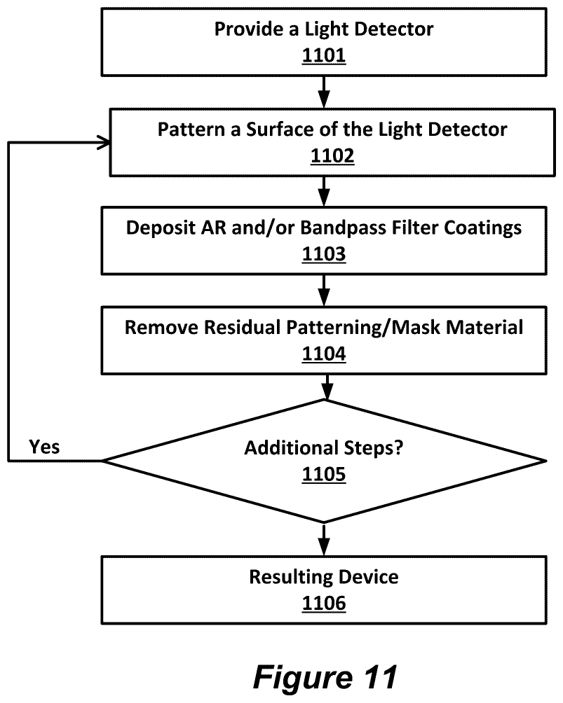

FIG. 11 is a flowchart that illustrates the steps for a process for area-selective ALD of AR and/or bandpass filter coatings, and a resulting manufactured device. Specifically, the flowchart illustrates the steps for a method comprising fabricating a device structure according to the present invention.

Block 1101 represents the step of providing a detector of electromagnetic radiation (e.g., a silicon-based light detector). The detector (e.g., silicon based light detector) may be passivated by a method such as ion implantation, etc. The silicon-based light detector may comprise a two dimensional (2D)-doped UV light detector, such as a delta-doped UV light detector or a superlattice-doped UV light detector.

Block 1102 represents the step of an intentional and controllable patterning of a surface of the detector (e.g., silicon-based light detector) e.g., by a lithography-based process. The intentional and controllable patterning is used to select different portions of the silicon-based light detector for each of one or more AR and/or bandpass filter coatings.

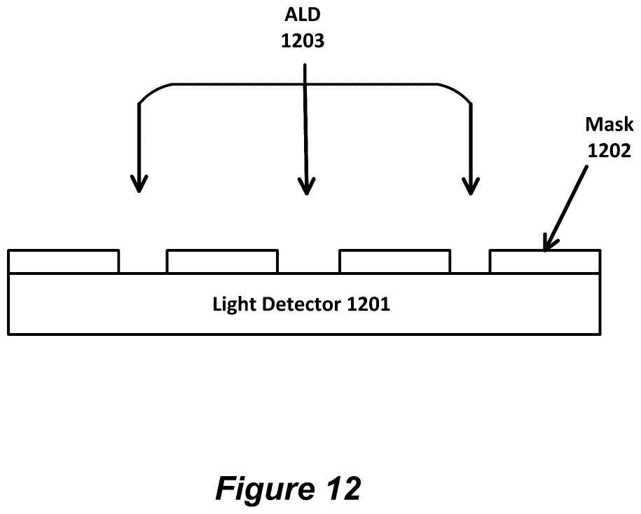

The inventors discovered that using separate physical mask to cover the areas where the coatings were not to be deposited works for other deposition techniques, but the coatings would be deposited under the physical mask using ALD. Thus, in this step, a lithography mask is placed directly on the surface of the detector, and replaces the separate physical mask, preventing deposition by ALD in unwanted areas. This area-selective ALD is illustrated in the schematic of FIG. 12, which illustrates the silicon-based light detector 1201, the lithography mask 1202 placed directly on the surface of the detector 1201, and the ALD 1203 of the AR and/or bandpass filter coatings onto exposed areas of the silicon-based light detector 1201, but not on the areas covered by the lithography mask 1202. The lithography mask 1202 is defined with a maskless alignment tool (Heidelberg MLA™), so the lithography mask 1202 can be defined in an arbitrary shape.

In various examples, standard commercial photoresist (e.g., −AZ P4330 photoresist) can be used.

Block 1103 represents the step of depositing one or more AR and/or bandpass filter coatings on the selected different portions of the detector (e.g., silicon-based light detector) by ALD, wherein the ALD is an area-selective ALD based on the intentional and controllable patterning.

The AR coatings may comprise a metal oxide or metal fluoride, such as AlF₃, Al₂O₃, and/or HfO₂, and the bandpass filter coatings may comprise solar-blind bandpass filter coatings. The bandpass filter coatings may be a Fabry Perot cavity comprising a reflective metal layer between two dielectric layers.

The AR and/or bandpass filter coatings are deposited with sub-nanometer precision. The AR and/or bandpass filter coatings may be deposited with different thicknesses on the different portions of the silicon-based light detector.

In one or more embodiments, a challenge of this step is that the photoresist materials used for the lithography mask 1202 were not stable at the ALD's process temperatures normally used (200° C. and higher). In such examples, the ALD processes had to be modified to run at a lower temperature (<115° C.), so that the integrity of the mask 1202 would not be compromised. The ALD can use processes and systems at lower temperature (below 115° C.) using the systems and methods described in refs. 30-32.

The AR and/or bandpass filter coatings each may have a bandwidth tailored for the different frequency response of the silicon to UV light, so that the detector has a quantum efficiency greater than 50% for UV wavelengths between 110 nm and 300 nm. In one or more examples, the AR and/or bandpass filter coatings have been patterned on a silicon-based light detector 1201 to intentionally result in a spatially varying response profile, rather than using detectors having a uniform response across the device/array. The ALD process 1203 allows for nanometer precision in the z-plane (i.e., film thickness) and the lithography-based process of Block 1102 allows for micron precision in the x-y plane (i.e. pixel-scale patterning capability).

Block 1104 represents the optional step of removing any residual patterning and/or mask material from the lithography-based process.

Block 1105 represents a decision block that determines whether additional steps, i.e., additional lithography and deposition of the AR and/or bandpass filter coatings, are necessary or desired. If so, Block 1102 is performed again; otherwise, Block 1106 is performed.

The above steps may be modified, eliminated, or repeated, without departing from the scope of the present invention.

Block 1106 represents the end results of the method, namely, a device manufactured by the above steps. In one or more examples, the device comprises a light detector with one or more AR and/or bandpass filter coatings deposited thereon, wherein the AR and/or bandpass filter coatings are deposited on different portions of the light detector and provide a butcher-block style response profile with each of the different portions of the light detector targeting a specific bandpass of the light. The AR and/or bandpass filter coatings together comprise one or more linear variable filters (LVFs) that provide a spatially varying response by the silicon-based light detector.

Other example devices and methods include, but are not limited to, the following (referring also to FIG. 7):

1. A device 700, comprising:
a detector 702 of electromagnetic radiation (e.g., light detector); and
one or more antireflection (AR) and/or bandpass filter coatings (or layers or films) 703-708 deposited on (e.g., a patterned surface) of the detector, wherein the AR and/or bandpass filter coatings are deposited on different portions 710 of the detector to provide a (e.g., butcher-block style) response profile (e.g., different anti-reflection/transmission and/or bandpass) with each of the different portions of the detector targeting a specific bandpass of light of and/or having a different/spatially varying photo response to the electromagnetic radiation.

2. The device of example 1, wherein the AR and/or bandpass filter coatings are deposited with different materials and/or different thicknesses T on the different portions of the detector.

3. The device of example 1 or 2, wherein the AR and/or bandpass filters are deposited with sub-nanometer precision.

4. The device of any of the examples 1-3, wherein the light detector comprises or consists essentially of a single material across the patterned surface.

5. The device of any of the examples 1-4, wherein the light detector comprises or consists essentially of silicon

6. The device of any of the examples 1-5, wherein the light detector comprises a delta doped or a superlattice doped surface layer providing passivation of a near-surface band structure.

7. The device of any of the examples 1-6, wherein the AR and/or bandpass filter coatings each have a bandwidth tailored for the different frequency response of the silicon to ultraviolet (UV) light, so that the detector has a quantum efficiency greater than 50% for UV wavelengths between 110 nm and 300 nm.

8. The device of any of the examples 1-7, wherein the AR coatings comprise a metal oxide or a metal fluoride and/or the filter is a Fabry Perot cavity comprising a reflective metal layer between two dielectric layers.

9. A system (e.g., spectrometer) comprising the device of any of the examples 1-8 with spatially varying response, where the electromagnetic radiation (e.g., light) optionally is dispersed with a prism or grating and/or the detector response as a function of position is designed to match the dispersion path of the system.

10. The device or system of any of the examples 1-9, wherein the detector comprises a semiconductor (e.g., silicon).

11. The device of any of the examples 1-10, wherein the detector comprises a Charge Coupled Device (CCD), silicon imager, silicon light detector, photodiode, photoconductor, etc.

12. The device of any of the examples 1-11, wherein the film/coatings 703-708 are deposited with nanometer precision in the z-plane (i.e., film thickness), e.g., precision in a range of 1-10 nm, positioned with micron precision (e.g., 1-100 microns) in the x-y plane (i.e. pixel-scale patterning capability).

13. The device of any of the examples 1-12, wherein the detector comprises an array of pixels and the coatings are deposited on the different portions comprising pixels (e.g., having a width of 1-1000 microns).

14. The device of any of the examples 1-13, wherein the detector has a spatially varying photo response (e.g., frequency response), so that each of the different portions (e.g. pixels) of the detector across an x-y plane of the detector have a different photoresponse/optical property (e.g., frequency response) to the electromagnetic radiation.

15. The device of any of the examples 1-14, wherein each of the one of the coatings/films are positioned and designed (e.g., thickness and/or material) to provide a bandwidth tailored for the frequency response of the portion of the detector on which the one of the coatings/films is deposited and matched, so as to obtain a desired photo response of the device (e.g., to match the dispersion path of the system in which the device is installed).

16. The device of any of the examples 1-15, wherein the different portions of the detector each detect a different range of wavelengths/frequency of the electromagnetic radiation and the coating/film on each of the different portions is designed as an AR coating or bandpass filter (e.g., thickness and/or material) for the different portion on which the coating/film is deposited.

17. The device of any of the examples 1-16, wherein each of the AR coatings/bandpass filter coatings have a (e.g., different/tailored/matched) AR (e.g., reflectivity, transmission) and/or bandpass tailored or matched for the (e.g., photoresponse of) the portion of the detector on which they are deposited.

18. The device of any of the examples 1-17, wherein the electromagnetic radiation comprises ultraviolet wavelengths.

19. FIGS. 11 and 12 illustrates a method, comprising:
providing a detector of electromagnetic radiation (Block 1101); and
selectively depositing (Blocks 1102-1103) one or more antireflection (AR) and/or bandpass filter coatings on the detector, wherein each of the AR and/or bandpass filter coatings are selectively deposited on a different surface portion of the light detector to provide (e.g., a butcher-block style) response profile (e.g., different anti-reflection/transmission) and/or bandpass) with each of the different portions of the detector at least targeting a specific bandpass of the electromagnetic radiation (e.g., light) or having a different photoresponse to the electromagnetic radiation.

20. The method of example 19, wherein the AR and/or bandpass filter coatings are deposited with different materials and/or different thicknesses on the different portions of the detector.

21. The method of example 19 or 20, wherein the AR and/or bandpass filter coatings are deposited by atomic layer deposition (ALD).

22. The method of any of the examples 19-21, wherein the ALD is an area-selective ALD.

23. The method of any of the examples 19-22, wherein the area-selective ALD comprises an intentional and controllable patterning by a lithography-based process.

24. The method of any of the examples 19-23, wherein a lithography mask is placed directly on a surface of the detector preventing deposition by ALD in unwanted areas.

25. The method of any of the examples 19-24, wherein the AR coatings comprise a metal oxide or metal fluoride.

26. The method of any of the examples 19-25, wherein the bandpass filter coatings comprise solar-blind bandpass filter coatings.

27. The method of any of the examples 19-26, wherein the AR and/or bandpass filter coatings together comprise one or more linear variable filters (LVFs) that provide a spatially varying response by the detector.

28. The method of any of the examples 19-27, wherein the light detector consists essentially of silicon.

29. The method of any of the examples 19-28, wherein the light detector comprises a two-dimensional (2D) doped detector, a 2D doped ultraviolet (UV) light detector, a delta-doped detector, a delta doped UV light detector, or a superlattice-doped detector, or superlattice doped UV light detector.

30. The device of any of the examples 1-18 manufactured using the method of any of the examples 19-29.

31. The device of any of the examples 1-30, wherein the filters/AR coating optimizing silicon detector photo response) and/or have been patterned on the silicon detector to intentionally result in a spatially varying response profile, rather than working with detectors with uniform response across the device/array.

32. The device of any of the examples 1-31, wherein each of the AR coatings or bandpass filters can deposited on a different one of the portions of the detector and the photoresponse can vary, e.g., in the x-y plane across the detector.

33. The device of any of the examples 1-32, wherein the detector (e.g., light detector, silicon light detector) has a spatially varying response (e.g., photoresponse) across a surface (e.g., x-y plane) of the detector on which the AR coating/filters are deposited.

7. Conclusions

This invention offers an innovative solution to the limitations and compromises inherent in traditional optical coating technologies by combining well-established lithographic patterning techniques with optical coating techniques. This advancement will result in detectors with high quantum efficiency in targeted wavelength bands, allowing for more versatile UV-Visible instrumentation including spectrometers. This invention will enable more affordable, and less complex, high-performance instruments.

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

8. References

The following publications are incorporated by reference herein:
1. Astrophysics Program Offices: Technology Development. 2022. https://apd440.gsfc.nasa.gov/technology.html Carver A. 2021. High performance modular and compact camera for ultraviolet instrumentation. Proc SPIE 11755: Sensors and Systems for Space Applications XIV, p. 2. SPIE.
2. Greer F, Hamden E, Jacquot B C, Hoenk M E, Jones T J, et al. 2013. Atomically precise surface engineering of silicon CCDs for enhanced UV quantum efficiency. Journal of Vacuum Science & Technology A: Vacuum, Surfaces, and Films. 31(1):01A103:9.
3. Hamden E, Martin D C, Milliard B, Schiminovich D, Nikzad S, et al. 2020. FIREBall-2: The Faint Intergalactic Medium Redshifted Emission Balloon Telescope. The Astrophysical Journal. 898(2):170.
4. Hamden E T, Jewell A D, Shapiro C A, Cheng S R, Goodsall T M, et al. 2016a. Charge-coupled devices detectors with high quantum efficiency at UV wavelengths. Journal of Astronomical Telescopes, Instruments, and Systems. 2(3):036003.
5. Hamden E T, Jewell A D, Shapiro C A, Cheng S R, Goodsall T M, et al. 2016b. Charge-coupled devices detectors with high quantum efficiency at UV wavelengths. Journal of Astronomical Telescopes, Instruments, and Systems. 2(3):036003.
6. Hennessy J, Jewell A D, Greer F, Lee M C, Nikzad S. 2015a. Atomic layer deposition of magnesium fluoride via bis(ethylcyclopentadienyl)magnesium and anhydrous hydrogen fluoride. Journal of Vacuum Science & Technology A. 33(1):01A125.
7. Hennessy J, Jewell A D, Hoenk M E, Hitlin D, McClish M, et al. 2018. Advanced imaging capabilities by incorporating plasmonics and metamaterials in detectors. Proc SPIE 10639: Micro- and Nanotechnology Sensors, Systems, and Applications X. 106391P:8. Orlando, FL, USA: SPIE.
8. Hennessy J, Jewell A D, Hoenk M E, Nikzad S. 2015b. Metal-dielectric filters for solar-blind silicon ultraviolet detectors. Applied Optics. 54(12).
9. Hoenk M E, Grunthaner P J, Grunthaner F J, Terhune R W, Fattahi M, Tseng H-F. 1992. Growth of a delta-doped silicon layer by molecular beam epitaxy on a charge-coupled device for reflection-limited ultraviolet quantum efficiency. Applied Physics Letters. 61(9):1084-86.
10. Hoenk M E, Jones T J, Dickie M R, Greer F, Cunningham T J, et al. 2009. Delta-doped Back-illuminated CMOS Imaging Arrays: Progress and Prospects. Proc SPIE 7419, Infrared Systems and Photoelectronic Technology IV. 7419:0T:15.
11. Jewell A D, Hamden E T, Ong H R, Hennessy J, Goodsall T, et al. 2015. Detector performance for the FIREBall-2 UV experiment. Proc SPIE 9601: UV, X-Ray, and Gamma-Ray Space Instrumentation for Astronomy XIX. 9601:0N:8.
12. Jewell A D, Hennessy J, Hoenk M E, Nikzad S. 2013. Wide band antireflection coatings deposited by atomic layer deposition. Proc SPIE 8820, Nanoepitaxy: Materials and Devices. 8820:0Z:9.
13. Kuschnerus P, Rabus H, Richter M, Scholze F, Werner L, Ulm G. 1998. Characterization of photodiodes as transfer detector standards in the 120 nm to 600 nm spectral range. Metrologia. 35(4):355-62.
14. Lee J, Lee J M, Oh H, Kim C, Kim J, et al. 2021. Inherently Area-Selective Atomic Layer Deposition of SiO2 Thin Films to Confer Oxide Versus Nitride Selectivity. Advanced Functional Materials. 31(33):1-10.
15. Line M R, Lothringer J, Barman T, Ardila D, Shkolnik E, et al. 2021. Testing Giant Extrasolar Planet Atmospheric Physics with UV-SCOPE. Bulletin of the American Astronomical Society. 53(1):1-2.
16. Liu T L, Bent S F. 2021. Area-Selective Atomic Layer Deposition on Chemically Similar Materials: Achieving Selectivity on Oxide/Oxide Patterns. Chemistry of Materials. 33(2):513-23.
17. Loyd P, Shkolnik E, Ardila D, Meadows V, Lincowski A, et al. 2021. Understanding Stellar Impacts on the Photochemistry of Rocky Planet Atmospheres with UV-SCOPE. Bulletin of the American Astronomical Society. 53(1):1-2.
18. Nikzad S, Hoenk M E, Greer F, Jacquot B, Monacos S, et al. 2012. Delta doped Electron-multiplied CCD with Absolute Quantum Efficiency over 50% in the near to far Ultraviolet Range for Single Photon Counting Applications. Applied Optics. 51(3):365-69.
19. Nikzad S, Jewell A D, Hoenk M E, Jones T J, Hennessy J, et al. 2017. High-efficiency UV/optical/NIR detectors for large aperture telescopes and UV explorer missions: development of and field observations with delta-doped arrays. Journal of Astronomical Telescopes, Instruments, and Systems. 3(03):036002.
20. Palik E D, ed. 1998. Handbook of Optical Constants of Solids. San Diego: Academic Press.
21. Puig-Suari J, Turner C, Ahlgren W. 2002. Development of the standard CubeSat deployer and a CubeSat class PicoSatellite. 2001 IEEE Aerospace Conference Proceedings (Cat No01TH8542). 1:347-53.
22. Scowen P A, Gayley K, Neiner C, Vasudevan G, Woodruff R A, et al. 2021. The Polstar High Resolution Spectropolarimetry MIDEX Mission. Proc SPIE 11819, UV/Optical/IR Space Telescopes and Instruments: Innovative Technologies and Concepts X, p. 1181908. SPIE.
23. Shkolnik E L. 2018. On the verge of an astronomy CubeSat revolution. Nature Astronomy. 2(5):374-78.
24. Shkolnik E L, Ardila D R, Barman T, Dressing C, Line M. 2021. UV-SCOPE: A MidEx Mission Concept for the Ultraviolet Spectroscopic Characterization Of Planets and their Environments. Bulletin of the American Astronomical Society. 53(1):1-3.
25. TFCalc: Thin Film Design Software for Windows. 2009.
26. Yarbrough J, Shearer A B, Bent S F. 2021. Next generation nanopatterning using small molecule inhibitors for area- selective atomic layer deposition. Journal of Vacuum Science & Technology A. 39(2):021002.
27. 2022 SPIE Astronomical Telescopes+Instrumentation. 12181-4; 12181-11; 12181-121.
28. Horiba UVISEL 2.
29. J. A. Woollam VUV-VASE.
30. Atomic layer deposition and etching methods for far ultraviolet aluminum mirrors, John Hennessy, Christopher S. Moore, Kunjithapatham Balasubramanian, April D. Jewell, Christian Carter, Kevin France, Shouleh Nikzad, “Atomic layer deposition and etching methods for far ultraviolet aluminum mirrors,” Proc. SPIE 10401, Astronomical Optics: Design, Manufacture, and Test of Space and Ground Systems, 1040119 (21 Sep. 2017); doi:10.1117/12.2274633
31. https://pubs.acs.org/doi/10.1021/acsami.9b15790
32. https://royalsocietypublishing.org/doi/10.1098/rsta.2017.0037
33. Selective-Area Atomic Layer Deposition Using Poly(methyl methacrylate) Films as Mask Layers Elina Fa\ddot{ }rm, * Marianna Kemell, Mikko Ritala, and Markku J. Phys. Chem. C 2008, 112, 15791-15795
34. Selective-Area Atomic Layer Deposition Using Poly(vinyl pyrrolidone) as a Passivation Layer Elina Färm,z Marianna Kemell, Eero Santala, * Mikko Rita Journal of The Electrochemical Society, 157_1_K10-K14_2010_

What is claimed is:

1. A method, comprising:
providing a detector of electromagnetic radiation; and
selectively depositing one or more antireflection (AR) and/or bandpass filter coatings on the detector, wherein the AR and/or bandpass filter coatings are selectively deposited on different portions of the light detector to provide a butcher-block style response profile with each of the different portions of the detector targeting a specific bandpass of the electromagnetic radiation and/or having a spatially varying photo-response to the electromagnetic radiation.

2. The method of claim 1, wherein the AR and/or bandpass filter coatings are deposited with different materials and/or different thicknesses on the different portions of the detector.

3. The method of claim 2, wherein the AR and/or bandpass filter coatings are deposited by atomic layer deposition (ALD).

4. The method of claim 3, wherein the ALD is an area-selective ALD.

5. The method of claim 4, wherein the area-selective ALD comprises an intentional and controllable patterning by a lithography-based process.

6. The method of claim 5, wherein a lithography mask is placed directly on a surface of the detector preventing deposition by ALD in unwanted areas.

7. The method of claim 1, wherein the AR coatings comprise a metal oxide or metal fluoride.

8. The method of claim 1, wherein the bandpass filter coatings comprise solar-blind bandpass filter coatings.

9. The method of claim 1, wherein the AR and/or bandpass filter coatings together comprise one or more linear variable filters (LVFs) that provide a spatially varying response by the detector.

10. The method of claim 1, wherein the light detector consists essentially of silicon.

11. The method of claim 1, wherein the light detector comprises a two-dimensional (2D) doped ultraviolet (UV) light detector, a delta-doped UV light detector, or a superlattice-doped UV light detector.

12. A device manufactured by the method of claim 1.

13. A device, comprising:
a detector of electromagnetic radiation; and
one or more antireflection (AR) and/or bandpass filter coatings deposited on a surface of the light detector, wherein the AR and/or bandpass filter coatings are deposited on different portions of the light detector to provide a butcher-block style response profile with each of the different portions of the detector targeting a specific bandpass of the electromagnetic radiation and/or having a spatially varying photo-response to the electromagnetic radiation.

14. The device of claim 13, wherein the AR and/or bandpass filter coatings are deposited with different materials and/or different thicknesses on the different portions of the detector.

15. The device of claim 13, wherein the AR and/or bandpass filters are deposited with sub-nanometer precision.

16. The device of claim 13, wherein the light detector consists essentially of a single material across the patterned surface.

17. The device of claim 16, wherein the light detector consists essentially of silicon.

18. The device of claim 17, wherein the light detector comprises a delta doped or a superlattice doped surface layer providing passivation of a near-surface band structure.

19. The device of claim 17, wherein the AR and/or bandpass filter coatings each have a bandwidth tailored for the different frequency response of the silicon to ultraviolet (UV) light, so that the detector has a quantum efficiency greater than 50% for UV wavelengths between 110 nm and 300 nm.

20. The device of claim 13, wherein the AR coatings comprise a metal oxide or a metal fluoride and/or the filter is a Fabry Perot cavity comprising a reflective metal layer between two dielectric layers.
